(19) United States
(12) Patent Application Publication
(10) Pub. No.: US 2023/0099844 A1
(43) Pub. Date: Mar. 30, 2023

(54) SEMICONDUCTOR PACKAGE

(71) Applicant: SAMSUNG ELECTRONICS CO., LTD., Suwon-si (KR)

(72) Inventors: Yong Ho KIM, Hwaseong-si (KR); Woo Jin JANG, Seoul (KR); Jeong Hoon AHN, Seongnam-si (KR); Yun Ki CHOI, Yongin-si (KR)

(73) Assignee: SAMSUNG ELECTRONICS CO., LTD., Suwon-si (KR)

(21) Appl. No.: 17/830,488

(22) Filed: Jun. 2, 2022

(30) Foreign Application Priority Data
Sep. 28, 2021 (KR) 10-2021-0128030

(51) Int. Cl. H01L 23/00; H01L 25/065

(52) U.S. Cl. CPC H01L 24/16; H01L 24/05; H01L 24/13; H01L 24/73; H01L 24/32; H01L 25/0657; H01L 25/0652; H01L 2225/06513; H01L 2225/06517; H01L 2225/06524; H01L 2225/06541; H01L 2224/73204; H01L 2224/32145; H01L 2224/16147; H01L 2224/16227; H01L 2224/16238; H01L 2224/16014; H01L 2224/16058; H01L 2224/13124; H01L 2224/16104; H01L 2224/05166; H01L 2224/05082; H01L 2224/05541; H01L 2224/05551; H01L 2224/05557; H01L 2224/05573; H01L 2224/05647; H01L 2924/1431; H01L 2924/1434

(57) ABSTRACT

Provided is a semiconductor package including a first chip substrate including a first surface and a second surface, a through via passing through the first chip substrate, an upper passivation layer including a trench on the second surface of the first chip substrate, the trench exposing at least a portion of the second surface of the first chip substrate, an upper pad electrically connected with the through via on the trench, a second chip substrate including a third surface and a fourth surface, a lower pad electrically connected to the second chip substrate on the third surface of the second chip substrate, and a connection bump electrically connecting the upper pad with the lower pad and contacting the lower pad, wherein a width of the connection bump increases as the connection bump becomes farther away from the first surface of the first chip substrate.

### CROSS-REFERENCE TO RELATED APPLICATION

This application claims priority to Korean Patent Application No. 10-2021-0128030 filed on Sep. 28, 2021 in the Korean Intellectual Property, the disclosure of which is incorporated herein by reference in its entirety.

### BACKGROUND

### 1. Field

Example embodiments of the present disclosure relate to a semiconductor package.

### 2. Description of Related Art

With rapid advancement of the electronic industry and demands of users, an electronic device is getting smaller and lightweight, and a semiconductor package used in the electronic device has been required to have high performance and large capacity together with miniaturization and light weight. In order to implement high performance and large capacity together with miniaturization and light weight, research and development of a semiconductor chip including a through silicon via structure (TSV) structure and a semiconductor package including the semiconductor chip are ongoing.

In particular, for miniaturization and light weight of the semiconductor package, contact stability of bumps and pads has been required.

### SUMMARY

One or more example embodiments provide a semiconductor package with improved contact stability.

The objects of the present disclosure are not limited to those mentioned above and additional objects of the present disclosure, which are not mentioned herein, will be clearly understood by those skilled in the art from the following description of the present disclosure.

According to an aspect of an example embodiment, there is provided a semiconductor package including a first chip substrate including a first surface and a second surface which are opposite to each other, a through via passing through the first chip substrate, an upper passivation layer including a trench on the second surface of the first chip substrate, the trench exposing at least a portion of the second surface of the first chip substrate, an upper pad electrically connected with the through via on the trench, a second chip substrate including a third surface opposite to the second surface and a fourth surface opposite to the third surface, a lower pad electrically connected with the second chip substrate on the third surface of the second chip substrate, and a connection bump electrically connecting the upper pad with the lower pad, the connection bump contacting the lower pad, wherein a width of the connection bump on the first surface of the first chip substrate increases as the connection bump becomes farther away from the first surface of the first chip substrate in a vertical direction.

According to another aspect of an example embodiment, there is provided a semiconductor package including a first semiconductor chip including an upper passivation layer having a trench, and an upper pad extending along a bottom surface of the trench and a sidewall of the trench and at least a portion of an upper surface of the upper passivation layer, a second semiconductor chip including a lower pad on the first semiconductor chip, a seed layer on the lower pad, and a connection bump between the upper pad and the seed layer, the connection bump electrically connecting the first semiconductor chip with the second semiconductor chip, wherein a width of the connection bump on the first semiconductor chip increases toward a first direction oriented toward the second semiconductor chip from the first semiconductor chip, and wherein a sidewall of the seed layer includes a portion recessed into the seed layer.

According to an aspect of an example embodiment, there is provided A semiconductor package including a first semiconductor chip including an upper passivation layer having a trench, and an upper pad extending along a bottom surface of the trench and a sidewall of the trench and at least a portion of an upper surface of the upper passivation layer, a second semiconductor chip including a lower pad on the first semiconductor chip, and a connection bump between the upper pad and the lower pad, the connection bump electrically connecting the first semiconductor chip with the second semiconductor chip, wherein a width of the connection bump on the first semiconductor chip increases toward a first direction oriented toward the second semiconductor chip from the first semiconductor chip, and wherein a melting point of a material of the connection bump is lower than a melting point of a material of the lower pad.

According to another aspect of an example embodiment, there is provided a semiconductor package including a package substrate, a plurality of first semiconductor chips sequentially on the package substrate in a first direction, an external connection terminal between the package substrate and the plurality of first semiconductor chips, the external connection terminal electrically connecting the package substrate with the plurality of first semiconductor chips, and a connection bump between the plurality of first semiconductor chips, the connection bump electrically connecting the plurality of first semiconductor chips with each other and including aluminum, wherein each of the plurality of first semiconductor chips includes a chip substrate including a first surface opposite to an upper surface of the package substrate and a second surface opposite to the first surface, a semiconductor device layer on the first surface of the chip substrate, a lower pad on the semiconductor device layer, a seed layer on the lower pad, an upper passivation layer including a trench on the second surface of the chip substrate, the trench exposing at least a portion of the second surface of the chip substrate, and an upper pad extending along a bottom surface of the trench and a sidewall of the trench and at least a portion of an upper surface of the upper passivation layer, including copper, wherein a width of the connection bump and a width of the trench on the upper surface of the package substrate increase as the connection bump and the trench become farther away from the upper surface of the package substrate in the first direction.

### BRIEF DESCRIPTION OF THE DRAWINGS

The above and/or other aspects and features of the present disclosure will become more apparent by describing in detail exemplary embodiments thereof with reference to the attached drawings, in which:

FIG. 1 is a view illustrating a semiconductor package according to embodiments;

FIG. 2 is an enlarged view illustrating a region R of FIG. 1;

FIGS. 3, 4, 5, 6, 7, and 8 are views illustrating a semiconductor package according to embodiments;

FIG. 9 is a view illustrating a semiconductor package according to embodiments;

FIG. 10 is a view illustrating a semiconductor package according to embodiments;

FIGS. 11, 12, 13, 14, and 15 are views illustrating intermediate steps to describe a method of manufacturing a semiconductor package according to embodiments; and

FIG. 16 is a view illustrating intermediate steps to describe a method of manufacturing a semiconductor package according to embodiments.

### DETAILED DESCRIPTION

Hereinafter, embodiments will be explained in detail with reference to the accompanying drawings. Embodiments described herein are example embodiments, and the present disclosure is not limited thereto.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

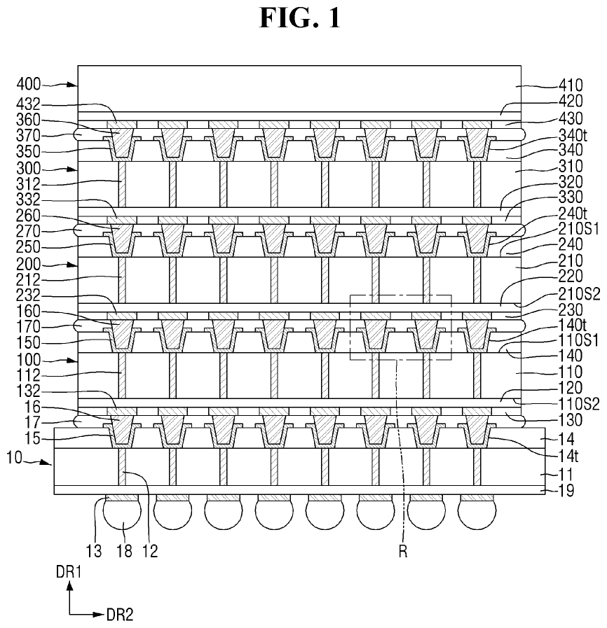

FIG. 1 is a view illustrating a semiconductor package according to embodiments.

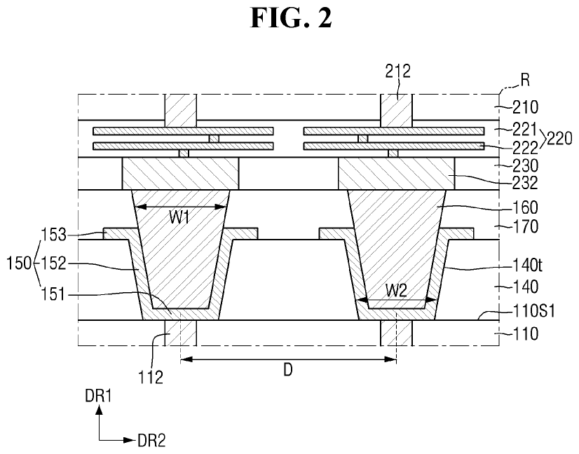

FIG. 2 is an enlarged view illustrating a region R of FIG. 1.

Referring to FIGS. 1 and 2, a semiconductor package according to embodiments may include a base chip 10, a first semiconductor chip 100, a second semiconductor chip 200, a third semiconductor chip 300 and a fourth semiconductor chip 400.

For example, the base chip 10 may be a dummy semiconductor chip that does not include individual devices, unlike the first to fourth semiconductor chips 100, 200, 300 and 400. For example, the base chip 10 may be a buffer chip that may receive at least one of a control signal, a power signal or a ground signal for controlling the operation of the first to fourth semiconductor chips 100, 200, 300 and 400 from the outside, receive data signals to be stored in the first to fourth semiconductor chips 100, 200, 300 and 400 from the outside or provide data stored in the first to fourth semiconductor chips 100, 200, 300 and 400 to the outside.

For example, the first to fourth semiconductor chips 100, 200, 300 and 400 may be memory semiconductor chips. The memory semiconductor chip may be, for example, a volatile memory semiconductor chip such as a dynamic random access memory (DRAM) or a static random access memory (SRAM), or a non-volatile memory semiconductor chip such as a phase-change random access memory (PRAM), a magneto resistive random access memory (MRAM), a ferroelectric random access memory (FeRAM) or a resistive random access memory (RRAM).

Although five semiconductor chips are shown as being stacked, this is only for convenience of description, and embodiments are not limited thereto.

The first to fourth semiconductor chips 100, 200, 300 and 400 may be disposed on the base chip 10. The first to fourth semiconductor chips 100, 200, 300 and 400 may sequentially be stacked on the base chip 10.

The first semiconductor chip 100 may include a first chip substrate 110, a first through via 112, a first semiconductor device layer 120, a first lower passivation layer 130, a first lower pad 132, a first upper passivation layer 140, and a first upper pad 150.

The first through via 112 may be disposed in the first chip substrate 110. The first through via 112 may pass through the first chip substrate 110.

The first semiconductor device layer 120 may be disposed on a lower surface 110S2 of the first chip substrate 110. The first semiconductor device layer 120 may electrically be connected with the first through via 112. In this case, the lower surface 110S2 of the first chip substrate 110 may be a lower side in a first direction DR1.

The first lower passivation layer 130 may be disposed on a lower surface of the first semiconductor device layer 120. The first lower passivation layer 130 may be provided adjacent to and surround the first lower pad 132. A lower surface of the first lower pad 132 may be exposed by the first lower passivation layer 130. The first lower pad 132 may electrically be connected with the first semiconductor device layer 120.

The first upper passivation layer 140 may be disposed on an upper surface 110S1 of the first chip substrate 110. The first upper passivation layer 140 may include a first trench 140t. The first trench 140t may expose at least a portion of the upper surface 110S1 of the first chip substrate 110. In this case, the upper surface 110S1 of the first chip substrate 110 may be an upper surface in the first direction DR1. The upper surface 110S1 of the first chip substrate 110 may be opposite to a lower surface 110S2 of the first chip substrate 110.

In embodiments, on the upper surface 110S1 of the first chip substrate 110, a width W2 of the first trench 140t may increase as the first trench 140t becomes farther away from the upper surface 110S1 of the first chip substrate 110 in the first direction DR1. For example, the width W2 of the first trench 140t may be increased toward the upper side in the first direction DR1.

In embodiments, on the upper surface 110S1 of the first chip substrate 110, the width W2 of the first trench 140t may be substantially constant as the first trench 140t becomes farther away from the upper surface 110S1 of the first chip substrate 110.

The first upper pad 150 may be disposed on the first trench 140t. The first upper pad 150 may be extended along the first trench 140t. The first upper pad 150 may include a first portion 151 extended along the upper surface 110S1 of the first chip substrate 110, which is exposed by the first trench 140t, a second portion 152 extended along a sidewall of the first trench 140t, and a third portion 153 extended along an upper surface of the first upper passivation layer 140. The second portion 152 may be connected with the first portion 151 and the third portion 153.

The first upper pad 150 may be spaced apart from another first upper pad 150 in a second direction DR2. In embodiments, a distance D between the centers of the first upper pads 150 adjacent to each other may be less than 20 μm. According to another embodiment, a distance D between the centers of the second lower pads 232 adjacent to each other may be less than 20 μm.

The second semiconductor chip 200 may be disposed on the first semiconductor chip 100. The second semiconductor chip 200 may include a second chip substrate 210, a second through via 212, a second semiconductor device layer 220, a second lower passivation layer 230, a second lower pad 232, a second upper passivation layer 240 and a second upper pad 250.

The second through via 212 may be disposed in the second chip substrate 210. The second through via 212 may pass through the second chip substrate 210.

The second semiconductor device layer 220 may be disposed on a lower surface 210S2 of the second chip substrate 210. The second semiconductor device layer 220 may electrically be connected with the second through via 212. The lower surface 210S2 of the second chip substrate 210 may be opposite to the upper surface 110S1 of the first chip substrate 110.

The second lower passivation layer 230 may be disposed on a lower surface of the second semiconductor device layer 220. The second lower passivation layer 230 may surround the second lower pad 232. A lower surface of the second lower pad 232 may be exposed by the second lower passivation layer 230. The second lower pad 232 may electrically be connected with the second semiconductor device layer 220.

The second upper passivation layer 240 may be disposed on an upper surface 210S1 of the second chip substrate 210. The second upper passivation layer 240 may include a second trench 240t. The second trench 240t may expose at least a portion of the upper surface 210S1 of the second chip substrate 210. The second trench 240t may have a structure substantially the same as that of the first trench 140t. The upper surface 210S1 of the second chip substrate 210 may be opposite to the lower surface 210S2 of the second chip substrate 210.

The second upper pad 250 may be disposed on the second trench 240t. The second upper pad 250 may be extended along the second trench 240t. The second upper pad 250 may have a structure substantially the same as that of the first upper pad 150.

A first connection bump 160 may be disposed between the first semiconductor chip 100 and the second semiconductor chip 200. The first connection bump 160 may be disposed between the first upper pad 150 and the second lower pad 232. On the upper surface 110S1 of the first chip substrate 110, a height of the first connection bump 160 may be greater than a distance between the first upper passivation layer 140 and the second lower passivation layer 230.

The first connection bump 160 may adjoin and contact at least a portion of the second lower pad 232 and at least a portion of the first upper pad 150. The first connection bump 160 may fill at least a portion of the first trench 140t. The first connection bump 160 may electrically be connected with the second lower pad 232 and the first upper pad 150.

For example, the first connection bump 160 may be in contact with the entirety of the second portion 152. The first connection bump 160 may be in contact with the first portion 151 and the second portion 152 to fill the first trench 140t. For example, the first connection bump 160 may be filled between the second portions 152 on the first portion 151.

In embodiments, the first connection bump 160 may have a truncated cone shape. On the upper surface 110S1 of the first chip substrate 110, a width W1 of the first connection bump 160 may increase as the first connection bump 160 becomes farther away from the upper surface 110S1 of the first chip substrate 110 in the first direction DR1.

In embodiments, the first connection bump 160 may have a cylindrical shape. On the upper surface 110S1 of the first chip substrate 110, the width W1 of the first connection bump 160 may be substantially constant as the first connection bump 160 becomes farther away from the upper surface 11051 of the first chip substrate 110.

In the semiconductor package according to embodiments, the width W1 of the first connection bump 160 and the width W2 of the first trench 140t may be increased as the first connection bump 160 and the first trench 140t become farther away from the upper surface 11051 of the first chip substrate 110 in the first direction DR1. For example, a sidewall of the first connection bump 160 and a sidewall of the second portion 152 of the first upper pad 150 may have a positive slope with respect to the upper surface 110S1 of the first chip substrate 110. In this case, an adhesive area between the first connection bump 160 and the first upper pad 150 may be more increased than the case that any one of the sidewall of the first connection bump 160 and the sidewall of the second portion 152 of the first upper pad 150 has a positive slope with respect to the upper surface 110S1 of the first chip substrate 110 and the other one has a negative slope with respect to the upper surface 110S1 of the first chip substrate 110. Therefore, a bonding force between the first connection bump 160 and the first upper pad 150 may be improved, and contact stability may be improved.

In the semiconductor package according to embodiments, on the upper surface 110S1 of the first chip substrate 110, the width W1 of the first connection bump 160 and the width W2 of the first trench 140t may be substantially constant as the first connection bump 160 and the first trench 140t become farther away from the upper surface 110S1 of the first chip substrate 110. Therefore, the bonding force between the first connection bump 160 and the first upper pad 150 may be improved.

A first inter-chip molding material 170 may be disposed between the first semiconductor chip 100 and the second semiconductor chip 200. The first inter-chip molding material 170 may be filled between the first semiconductor chip 100 and the second semiconductor chip 200. The first inter-chip molding material 170 may cover the first upper passivation layer 140 and the first upper pad 150. The first inter-chip molding material 170 may surround the first connection bump 160.

The third semiconductor chip 300 may include a third chip substrate 310, a third through via 312, a third semiconductor device layer 320, a third lower passivation layer 330, a third lower pad 332, a third upper passivation layer 340, and a third upper pad 350.

The third through via 312 may pass through the third chip substrate 310. The third semiconductor device layer 320 may be disposed on a lower surface of the third chip substrate 310. The third semiconductor device layer 320 may electrically be connected with the third through via 312.

The third lower passivation layer 330 may be disposed on a lower surface of the third semiconductor device layer 320. The third lower passivation layer 330 may surround the third lower pad 332. A lower surface of the third lower pad 332 may be exposed by the third lower passivation layer 330. The third lower pad 332 may electrically be connected with the third semiconductor device layer 320.

The third upper passivation layer 340 may be disposed on an upper surface of the third chip substrate 310. The third upper passivation layer 340 may include a third trench 340t. The third trench 340t may expose at least a portion of the upper surface of the third chip substrate 310. The third trench 340t may have a structure substantially the same as that of the first trench 140t.

The third upper pad 350 may be disposed on the third trench 340t. The third upper pad 350 may be extended along the third trench 340t. The third upper pad 350 may have a structure substantially the same as that of the first upper pad 150.

A second connection bump 260 may be disposed between the second semiconductor chip 200 and the third semiconductor chip 300. The second connection bump 260 may be disposed between the second upper pad 250 and the third lower pad 332. On the upper surface 210S1 of the second chip substrate 210, a height of the second connection bump 260 may be greater than a distance between the second upper passivation layer 240 and the third lower passivation layer 330.

The second connection bump 260 may adjoin and contact at least a portion of the third lower pad 332 and at least a portion of the second upper pad 250. The second connection bump 260 may fill at least a portion of the second trench 240t. The second connection bump 260 may electrically be connected with the third lower pad 332 and the second upper pad 250. The second connection bump 260 may have a structure substantially the same as that of the first connection bump 160.

A second inter-chip molding material 270 may be disposed between the second semiconductor chip 200 and the third semiconductor chip 300. The second inter-chip molding material 270 may be filled between the second semiconductor chip 200 and the third semiconductor chip 300. The second inter-chip molding material 270 may cover the second upper passivation layer 240 and the second upper pad 250. The second inter-chip molding material 270 may be provided adjacent to and surround the second connection bump 260.

The fourth semiconductor chip 400 may include a fourth chip substrate 410, a fourth semiconductor device layer 420, a fourth lower passivation layer 430, and a fourth lower pad 432.

The fourth lower passivation layer 430 may be disposed on a lower surface of the fourth semiconductor device layer 420. The fourth lower passivation layer 430 may surround the fourth lower pad 432. A lower surface of the fourth lower pad 432 may be exposed by the fourth lower passivation layer 430. The fourth lower pad 432 may electrically be connected with the fourth semiconductor device layer 420.

A third connection bump 360 may be disposed between the third semiconductor chip 300 and the fourth semiconductor chip 400. The third connection bump 360 may be disposed between the third upper pad 350 and the fourth lower pad 432. On the upper surface of the third chip substrate 310, a height of the third connection bump 360 may be greater than a distance between the third upper passivation layer 340 and the fourth lower passivation layer 430.

The third connection bump 360 may adjoin and contact at least a portion of the fourth lower pad 432 and at least a portion of the third upper pad 350. The third connection bump 360 may fill at least a portion of the third trench 340t. The third connection bump 360 may electrically be connected with the fourth lower pad 432 and the third upper pad 350. The third connection bump 360 may have a structure substantially the same as that of the first connection bump 160.

A third inter-chip molding material 370 may be disposed between the third semiconductor chip 300 and the fourth semiconductor chip 400. The third inter-chip molding material 370 may be filled between the third semiconductor chip 300 and the fourth semiconductor chip 400. The third inter-chip molding material 370 may cover the third upper passivation layer 340 and the third upper pad 350. The third inter-chip molding material 370 may be provided adjacent to and surround the third connection bump 360.

The base chip 10 may include a base chip substrate 11, a base through via 12, a base lower pad 13, a base upper passivation layer 14, and a base upper pad 15. For example, the base chip 10 may have a width greater than a width of each of the first to fourth semiconductor chips 100, 200, 300 and 400.

The base through via 12 may be disposed in the base chip substrate 11. The base through via 12 may pass through the base chip substrate 11.

Each shape in which the first to third through vias 112, 212 and 312 and the base through via 12 are extended may be varied depending on a manufacturing process. For example, each of the first to third through vias 112, 212 and 312 and the base through via 12 may have a tapered shape. For example, each of the first to third through vias 112, 212 and 312 and the base through via 12 may have a cylindrical shape.

The base semiconductor device layer 19 may be disposed on a lower surface of the base chip substrate 11. The base semiconductor device layer 19 may electrically be connected with the base through via 12.

The base lower pad 13 may be disposed on a lower surface of the base semiconductor device layer 19. The base lower pad 13 may electrically be connected with the base semiconductor device layer 19. A passivation layer for protecting the base semiconductor device layer 19 may further be formed on a lower surface of the base lower pad 13. The passivation layer may expose at least a portion of the lower surface of the base lower pad 13.

A first external connection terminal 18 may be disposed on the base lower pad 13. The first external connection terminal 18 may electrically be connected with the base lower pad 13.

The first external connection terminal 18 may include, but is not limited to, at least one of a solder ball, a bump, an under bump metallurgy (UBM), or their combination. The first external connection terminal 18 may include, but is not limited to, a metal such as, for example, tin (Sn).

The base upper passivation layer 14 may be disposed on an upper surface of the base chip substrate 11. The base upper passivation layer 14 may include a base trench 14t. The base trench 14t may expose at least a portion of the upper surface of the base chip substrate 11. The base trench 14t may have a structure substantially the same as that of the first trench 140t.

The base upper pad 15 may be disposed on the base trench 14t. The base upper pad 15 may be extended along the base trench 14t. The base upper pad 15 may have a structure substantially the same as that of the first upper pad 150.

The base connection bump 16 may be disposed between the base chip 10 and the first semiconductor chip 100. The base connection bump 16 may be disposed between the base upper pad 15 and the first lower pad 132. On the upper surface of the base chip substrate 11, a height of the base connection bump 16 may be greater than a distance between the base upper passivation layer 14 and the first lower passivation layer 130.

The base connection bump 16 may adjoin and contact at least a portion of the first lower pad 132 and at least a portion of the base upper pad 15. The base connection bump 16 may fill at least a portion of the base trench 14t. The base connection bump 16 may electrically be connected with the first lower pad 132 and the base upper pad 15. The base connection bumps 16 may have a structure substantially the same as that of the first connection bump 160.

An inter-chip molding material 17 may be disposed between the base chip 10 and the first semiconductor chip 100. The inter-chip molding material 17 may be filled between the base chip 10 and the first semiconductor chip 100. The inter-chip molding material 17 may cover the base upper passivation layer 14 and the base upper pad 15. The inter-chip molding material 17 may be provided adjacent to and surround the base connection bump 16.

Each of the first to fourth chip substrates 110, 210, 310 and 410 and the base chip substrate 11 may be a bulk silicon or silicon-on-insulator (SOI). According to another embodiment, each of the first to fourth chip substrates 110, 210, 310 and 410 and the base chip substrate 11 may be a silicon substrate, or may include other material such as silicon germanium, silicon germanium on insulator (SGOI), indium antimonide, lead telluride compound, indium arsenide, indium phosphide, gallium arsenide or gallium antimonide, but is not limited thereto.

Each of the first to third through vias 112, 212 and 312 and the base through via 12 may include a conductive material. Each of the first to third through vias 112, 212 and 312 and the base through via 12 may include, but is not limited to, at least one of copper (Cu), Cu alloy such as bronze (CuSn), copper-magnesium (CuMg), copper-nickel (CuNi), copper-zinc (CuZn), copper-palladium (CuPd), copper-gold (CuAu), copper-rhenium (CuRe) and copper-tungsten (CuW), W, W alloy, Ni, ruthenium (Ru) or cobalt (Co).

Each of the first to fourth semiconductor device layers 120, 220, 320 and 420 and the base semiconductor device layer 19 may include various kinds of individual devices and an inter-wiring insulating layer. The individual devices may include a variety of microelectronic devices, for example, a metal-oxide-semiconductor field effect transistor (MOSFET) such as a complementary metal-insulator-semiconductor (CMOS) transistor, a system large scale integration (LSI), a flash memory, a DRAM, an SRAM, an EEPROM, a PRAM, an MRAM, a RRAM, an image sensor such as a CMOS imaging sensor (CIS), a micro-electro-mechanical system (MEMS), an active device, a passive device and the like.

Each of the first to fourth lower pads 132, 232, 332 and 432 and the base lower pad 13 may include at least one of aluminum (Al), copper (Cu), nickel (Ni), tungsten (W), platinum (Pt) or gold (Au).

The first to third upper pads 150, 250 and 350 and the base upper pad 15 may include at least one of, for example, aluminum (Al), copper (Cu), nickel (Ni), tungsten (W), platinum (Pt) or gold (Au).

In embodiments, each of the first to third connection bumps 160, 260 and 360 and the base connection bump 16 may not include tin (Sn). Each of the first to third connection bumps 160, 260 and 360 and the base connection bump 16 may have a melting point lower than that of each of the first to third upper pads 150, 250 and 350 and the base upper pad 15, and may include a material that may be subjected to a dry etching process. Each of the first to third connection bumps 160, 260 and 360 and the base connection bump 16 may include a material that does not excessively generate an inter metallic compound (IMC) with each of the first to third upper pads 150, 250 and 350 and the base upper pad 15.

For example, when each of the first to third upper pads 150, 250 and 350 and the base upper pad 15 includes copper, each of the first to third connection bumps 160, 260 and 360 and the base connection bump 16 may have a melting point lower than 1085° C., and may include a material that may be subjected to a dry etching process. For example, each of the first to third connection bumps 160, 260 and 360 and the base connection bump 16 may include aluminum, and each of the first to third upper pads 150, 250 and 350 and the base upper pad 15 may include copper.

In embodiments, each of the first to third connection bumps 160, 260 and 360 and the base connection bump 16 may include the same material as that of each of the first to third upper pads 150, 250 and 350 and the base upper pad 15. For example, each of the first to third connection bumps 160, 260 and 360, the base connection bump 16, the first to third upper pads 150, 250 and 350 and the base upper pad 15 may include aluminum. When the first to third upper pads 150, 250 and 350 and the base upper pad 15 include copper, since the first to third upper pads 150, 250 and 350 and the base upper pad 15 are formed by a dual damascene process, a planarization chemical mechanical planarization (CMP) process is accompanied. However, when each of the first to third upper pads 150, 250 and 350 and the base upper pad 15 includes aluminum, since a planarization process is omitted, the process of forming the first to third upper pads 150, 250 and 350 and the base upper pad 15 may be simplified.

Each of the first to third inter-chip molding materials 170, 270 and 370 and the inter-chip molding material 17 may include, for example, an insulating polymer material such as EMC, but is not limited thereto.

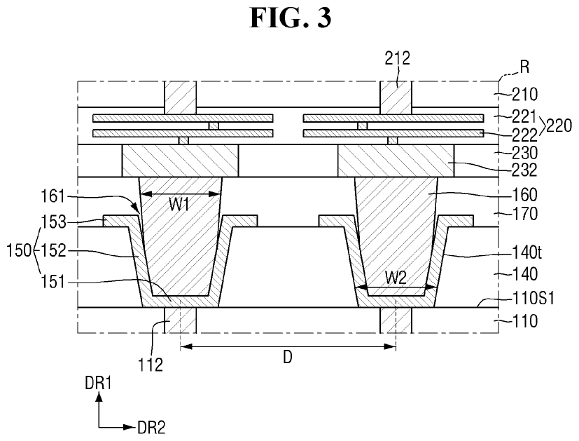

FIGS. 3 to 8 are views illustrating a semiconductor package according to embodiments. For reference, FIGS. 3 to 8 are enlarged views of the region R of FIG. 1. For convenience of description, the following description will be based on a difference from that made with reference to FIGS. 1 and 2.

Referring to FIG. 3, the semiconductor package according to embodiments may include an air gap 161 between the first connection bump 160 and the first upper pad 150.

For example, the air gap 161 may be formed between the first connection bump 160 and the second portion 152 of the first upper pad 150. In the first upper passivation layer 140, a lower portion of the first connection bump 160 may be in contact with the first upper pad 150, and an upper portion of the first connection bump 160 may be spaced apart from the first upper pad 150 by the air gap 161.

For example, a slope of the sidewall of the first connection bump 160, which adjoins and contacts the second portion 152, may differ from that of the sidewall of the first connection bump 160 spaced apart from the second portion 152 by the air gap 161.

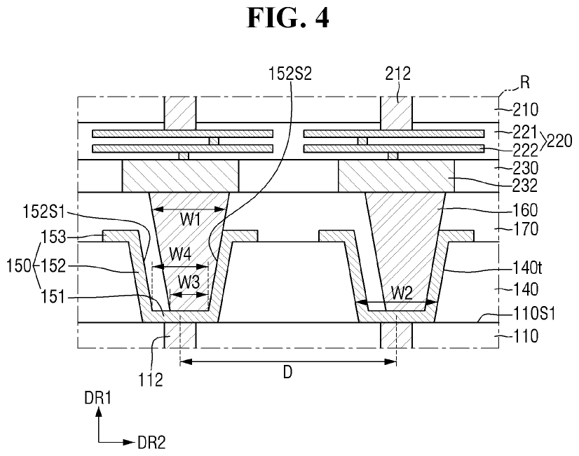

Referring to FIG. 4, in the semiconductor package according to embodiments, the second portion 152 of the first upper pad 150 may include a first sidewall 152S1 and a second sidewall 152S2, which are opposite to each other in the first upper passivation layer 140.

A width W4 of an upper surface of the first portion 151 of the first upper pad 150 in the second direction DR2 may be greater than a width W3 of a lower surface of the first connection bump 160 in the second direction DR2. The first connection bump 160 may be in contact with any one of the first and second side walls 152S1 and 152S2. For example, the first connection bump 160 may not be in contact with the first sidewall 152S1, and may be in contact with the second sidewall 152S2, or the first connection bump 160 may be in contact with the first sidewall 152S1 and may not be in contact with the second sidewall 152S2.

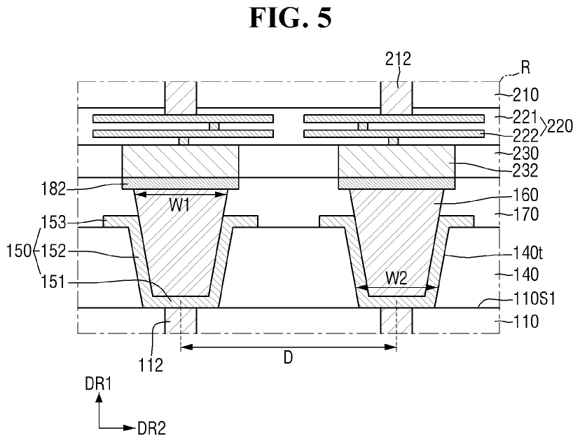

Referring to FIG. 5, the semiconductor package according to embodiments may further include a second seed layer 182. The second seed layer 182 may be disposed between the second lower pad 232 and the first connection bump 160. The second seed layer 182 may be extended along the lower surface of the second lower pad 232.

In embodiments, the width W1 of the first connection bump 160 in the second direction DR2 may be smaller than a width of the second seed layer 182. In embodiments, a width of an upper surface of the first connection bump 160 in the second direction DR2 may substantially be the same as a width of a lower surface of the second seed layer 182.

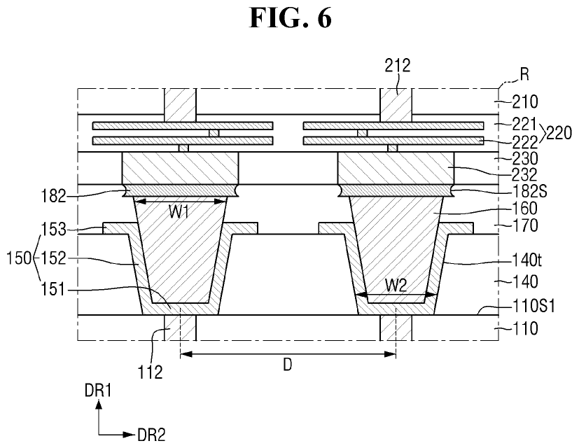

Referring to FIG. 6, in the semiconductor package according to embodiments, a sidewall 182S of the second seed layer 182 may include a portion recessed into the second seed layer 182. The sidewall 182S of the second seed layer 182 may include a portion convex toward the second seed layer 182. The width of the second seed layer 182 in the second direction DR2 may be reduced and then increased in the first direction DR1. A shape of the sidewall 182S of the second seed layer 182 may be caused by the process of forming the second seed layer 182.

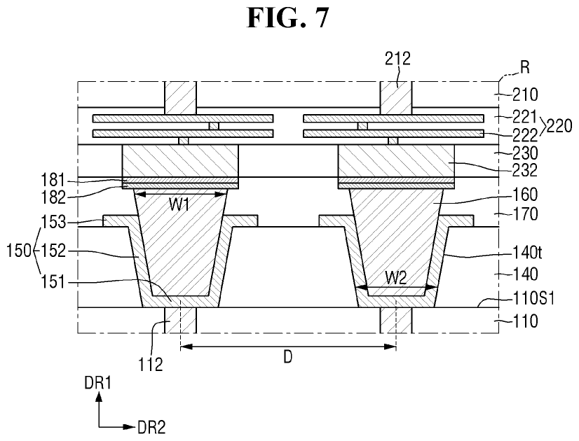

Referring to FIG. 7, the semiconductor package according to embodiments may include a first seed layer 181 and a second seed layer 182. The first seed layer 181 may be disposed between the second lower pad 232 and the second seed layer 182. The second seed layer 182 may be disposed between the first seed layer 181 and the first connection bump 160.

The first seed layer 181 may include, for example, titanium (Ti), but is not limited thereto. The second seed layer 182 may include, for example, copper (Cu), but is not limited thereto.

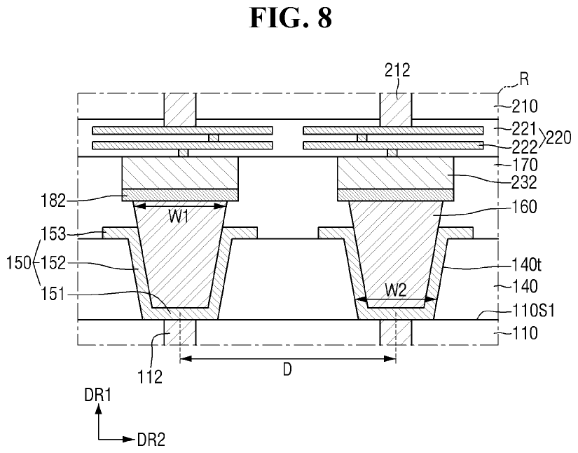

Referring to FIG. 8, in the semiconductor package according to embodiments, the second lower pad 232 may be disposed on the lower surface of the second semiconductor device layer 220. The first inter-chip molding material 170 may surround the second lower pad 232 and the second seed layer 182. For example, the semiconductor package according to embodiments may not include the second lower passivation layer 230 of FIG. 2.

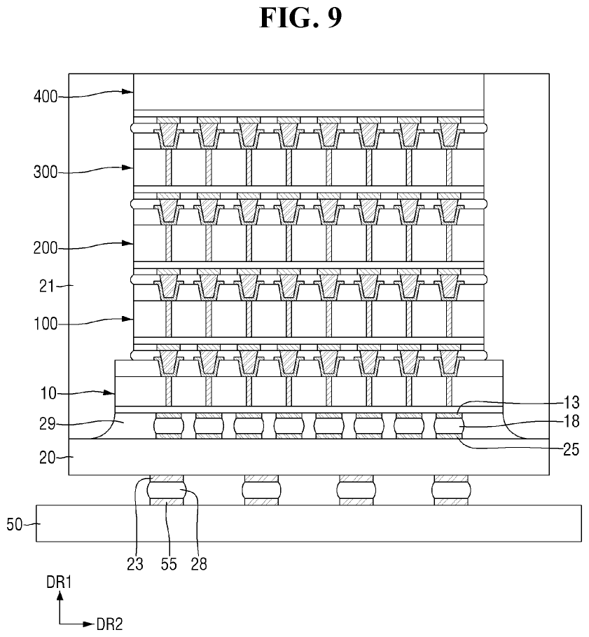

FIG. 9 is a view illustrating a semiconductor package according to embodiments. For convenience of description, the following description will be based on a difference from that made with reference to FIGS. 1 and 2.

Referring to FIG. 9, the semiconductor package according to embodiments may further include a package substrate 50 and a logic semiconductor chip 20.

The package substrate 50 may be, for example, a printed circuit board (PCB) or a ceramic substrate.

The logic semiconductor chip 20 may be disposed on the package substrate 50. The logic semiconductor chip 20 may be an integrated circuit (IC) in which several hundreds to millions of semiconductor devices are integrated into one chip. For example, the logic semiconductor chip 20 may be an application processor such as a central processing unit (CPU), a graphic processing unit (GPU), a field-programmable gate array (FPGA), a digital signal processor, an encryption processor, a microprocessor and a microcontroller, but is not limited thereto. For example, the logic semiconductor chip 20 may be a logic chip such as an analog-to-digital converter (ADC) or an application-specific integrated circuit (ASIC), or may be a memory chip such as a volatile memory (e.g., DRAM) or a non-volatile memory (e.g., ROM or flash memory). In addition, the logic semiconductor chip 20 may be configured in combination of the logic chip and the memory chip.

A second external connection terminal 28 may be disposed between the package substrate 50 and the logic semiconductor chip 20. The second external connection terminal 28 may be disposed between a substrate pad 55 of the package substrate 50 and a lower chip pad 23 of the logic semiconductor chip 20. The second external connection terminal 28 may electrically be connected with the package substrate 50 and the logic semiconductor chip 20.

The second external connection terminal 28 may include, but is not limited to, at least one of a solder ball, a bump, an under bump metallurgy (UBM), or their combination. The second external connection terminal 28 may include, but is not limited to, a metal such as tin (Sn), for example.

The base chip 10 may be disposed on the logic semiconductor chip 20. The first external connection terminal 18 may be disposed between the base lower pad 13 of the base chip 10 and an upper chip pad 25 of the logic semiconductor chip 20. The first external connection terminal 18 may electrically connect the base lower pad 13 of the base chip 10 with the upper chip pad 25 of the logic semiconductor chip 20.

An underfill material layer 29 may be disposed on the logic semiconductor chip 20. The underfill material layer 29 may be disposed between the base chip 10 and the logic semiconductor chip 20. The underfill material layer 29 may be filled between the base chip 10 and the logic semiconductor chip 20. The underfill material layer 29 may be provided adjacent to and surround the base lower pad 13, the first external connection terminal 18 and the upper chip pad 25.

The underfill material layer 29 may include, for example, an insulating polymer material such as epoxy mold compounds (EMC), but is not limited thereto.

A molding member 21 may be disposed on the logic semiconductor chip 20. The molding member 21 may cover at least a portion of the base chip 10 and at least a portion of the first to fourth semiconductor chips 100, 200, 300 and 400. For example, the molding member 21 may cover a side of the base chip 10 and sides of the first to fourth semiconductor chips 100, 200, 300 and 400. The molding member 21 may expose, for example, an upper surface of the fourth semiconductor chip 400. For example, the molding member 21 may cover the upper surface of the fourth semiconductor chip 400.

The molding member 21 may include, for example, an insulating polymer material such as EMC, but is not limited thereto. In embodiments, the first to third inter-chip molding materials 170, 270 and 370, the inter-chip molding material 17 and the underfill material layer 29 may include an insulating material having greater fluidity than that of the molding member 21.

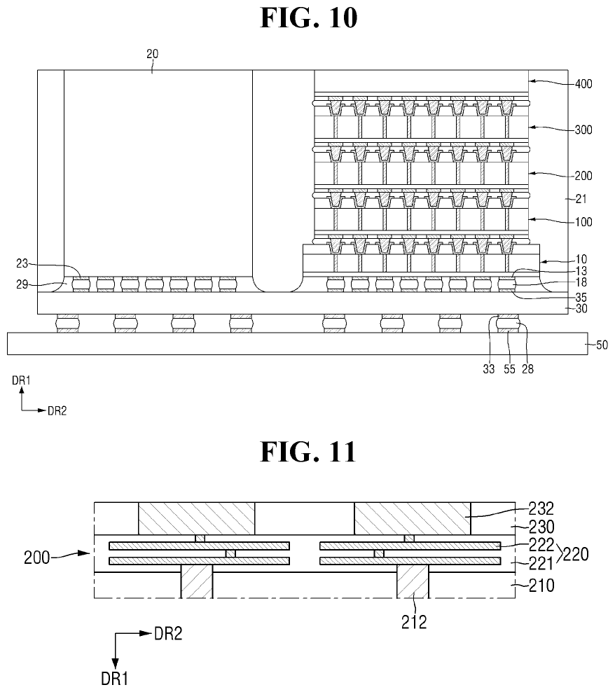

FIG. 10 is a view illustrating a semiconductor package according to embodiments. For convenience of description, the following description will be based on a difference from that made with reference to FIG. 9.

Referring to FIG. 10, in the semiconductor package according to embodiments, the interposer 30 may further include an interposer 30.

The interposer 30 may be disposed on the package substrate 50. The second external connection terminal 28 may be disposed between the package substrate 50 and the interposer 30. The second external connection terminal 28 may be disposed between a lower interposer pad 33 of the interposer 30 and an upper substrate pad 55 of the package substrate 50. The second external connection terminal 28 may electrically be connected with the package substrate 50 and the logic semiconductor chip 20.

The logic semiconductor chip 10 and the first to fourth semiconductor chips 100, 200, 300 and 400 may be disposed on the interposer 30. The logic semiconductor chip 10 and the first to fourth semiconductor chips 100, 200, 300 and 400 may be spaced apart from one another in the second direction DR2. The first external connection terminal 18 may be disposed between the lower chip pad 23 of the logic semiconductor chip 20 and an upper interposer pad 35 of the interposer 30. The first external connection terminal 18 may electrically be connected with the logic semiconductor chip 20 and the interposer 30. The first external connection terminal 18 may be disposed between the base lower pad 13 of the base chip 10 and the upper interposer pad 35 of the interposer 30. The first external connection terminal 18 may electrically be connected with the base chip 10 and the interposer 30. The logic semiconductor chip 20 and the base chip 10 may electrically be connected with each other through the interposer 30.

FIGS. 11 to 15 are views illustrating intermediate steps to describe a method of manufacturing a semiconductor package according to embodiments. FIGS. 11 to 15 are enlarged views of the region R of FIG. 1.

Referring to FIG. 11, the second semiconductor chip 200 may be provided. The second semiconductor chip 200 may include a second chip substrate 210 having a second through via 212, a second semiconductor device layer 220, and a second lower passivation layer 230.

The second semiconductor device layer 220 may include a plurality of wiring layers 222 and an insulating layer 221 provided adjacent to and surrounding the plurality of wiring layers 222. The wiring layer 222 may electrically be connected with the second through via 212.

The second lower pad 232 may be disposed in the lower passivation layer 230. The lower passivation layer 230 may be provided adjacent to and surround the second lower pad 232. The second lower pad 232 may electrically be connected with the wiring layer 222.

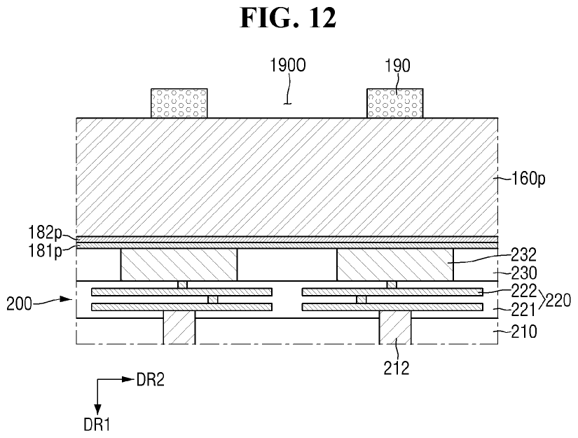

Referring to FIG. 12, a first pre-seed layer 181p and a second pre-seed layer 182p may sequentially be formed on the second lower passivation layer 230 and the second lower pad 232. The first pre-seed layer 181p may be extended along the lower surface of the second lower passivation layer 230 and the lower surface of the second lower pad 232 in the first direction DR1. The second pre-seed layer 182p may be extended along a lower surface of the first pre-seed layer 181p in the first direction DR1.

A first pre-connection bump 160p may be formed on the second pre-seed layer 182p.

A mask 190 may be formed on the first pre-connection bump 160p. The mask 190 may include an opening 1900 that exposes at least a portion of a lower surface of the first pre-connection bump 160p in the first direction DR1. The mask 190 may overlap the second lower pad 232 in the first direction DR1.

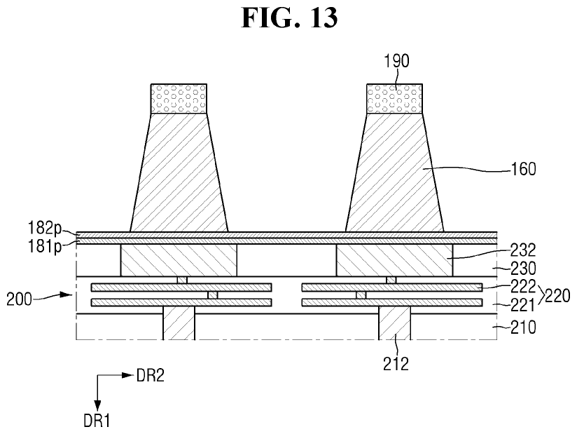

Referring to FIG. 13, the first pre-connection bump 160p may be etched by an etching process using the mask 190 to form the first connection bump 160.

In embodiments, the first pre-connection bump 160p may include aluminum. The etching process may be, for example, a dry etching process. Aluminum has a lower difficulty in the dry etch process as compared with copper. Therefore, the manufacturing process of the semiconductor package according to embodiments may have a lower difficulty.

The first connection bump 160 may have a tapered shape by the etching process. A width of the first connection bump 160 in the second direction DR2 may be increased in the first direction DR1.

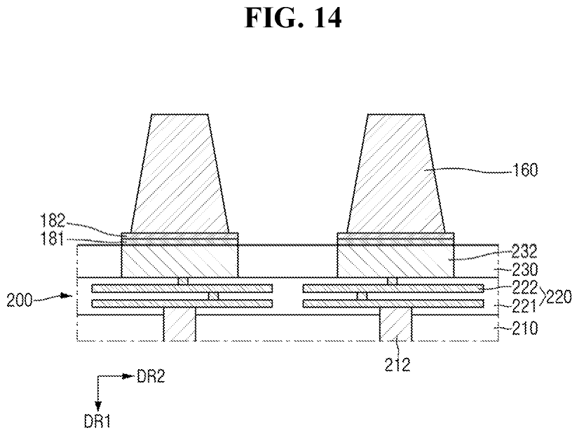

Referring to FIG. 14, the first pre-seed layer 181p and the second pre-seed layer 182p may be etched by the etching process to form the first seed layer 181 and the second seed layer 182. The etching process may be, for example, a plasma etching process, a dry etching process, or a wet etching process. When the first pre-seed layer 181p and the second pre-seed layer 182p are etched by the dry etching process, as shown in FIG. 6, a sidewall of the second seed layer 182 may include a portion recessed toward the second seed layer 182. A sidewall of the first seed layer 181 may also include a portion recessed toward the first seed layer 181. In addition, the mask 190 may be removed.

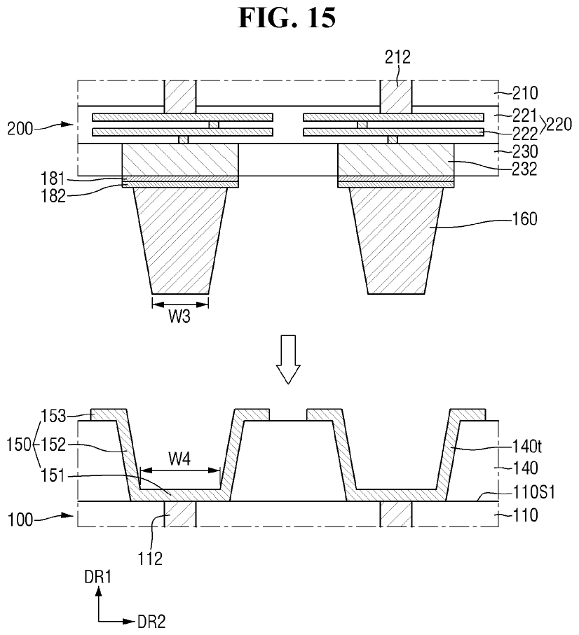

Referring to FIG. 15, the second semiconductor chip 200 may be disposed on the first semiconductor chip 100.

The first semiconductor chip 100 may include a first chip substrate 110 having a first through via 112, a first upper passivation layer 140, and a first upper pad 150. The first upper pad 150 may include a first portion 151 extended along a bottom surface of the first trench 140t, a second portion 152 extended along a sidewall of the first trench 140t, and a third portion 153 extended along at least a portion of the upper surface of the first upper passivation layer 140.

The second semiconductor chip 200 may be positioned so that the lower surface of the first connection bump 160 is opposite to the first upper pad 150. The lower surface of the first connection bump 160 may be opposite to the first portion 151 of the first upper pad 150.

Subsequently, the second semiconductor chip 200 and the first semiconductor chip 100 may be bonded to each other. Heat may be applied to the first connection bump 160 so that the first connection bump 160 and the first upper pad 150 may be bonded to each other. The first connection bump 160 and the first upper pad 150 may be bonded to each other by their diffusion. The first connection bump 160 may be deformed to fill the first trench 140t. At this time, as shown in FIG. 3, the air gap 161 may be formed between the first connection bump 160 and the first upper pad 150.

At this time, a melting point of the first connection bump 160 may be lower than that of the first upper pad 150. Therefore, the semiconductor package according to embodiments may bond the first connection bump 160 and the first upper pad 150 to each other at a lower temperature.

When the first connection bump 160 includes tin (Sn), an intermetallic compound is excessively or very quickly grown during bonding of the first connection bump 160 and the first upper pad 150. Therefore, in the semiconductor package where an interval between the first upper pads 150 becomes narrow, use of the first connection bump 160 that includes tin is restricted due to a bonding defect of the first connection bump 160 and the first upper pad 150.

However, in the semiconductor package according to embodiments, since the first connection bump 160 includes aluminum instead of tin, the growth of the intermetallic compound may be slower. Therefore, even though the interval between the first upper pads 150 becomes narrow, the bonding defect due to the intermetallic compound may be reduced, and the bonding force between the first connection bump 160 and the first upper pad 150 may be improved.

In embodiments, the width W4 of the first portion 151 in the second direction DR2 may be greater than the width W3 of the lower surface of the first connection bump 160. Therefore, even though the first connection bump 160 is not aligned on the first upper pad 150, the first connection bump 160 and the first upper pad 150 may be bonded to each other.

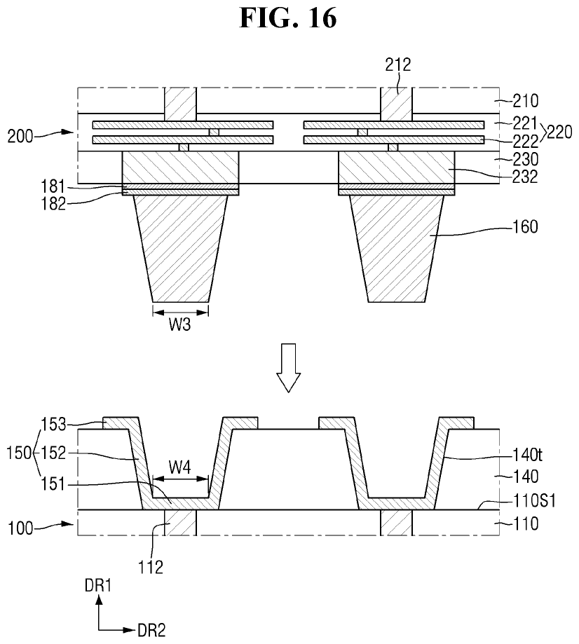

FIG. 16 is a view illustrating intermediate steps to describe a method of manufacturing a semiconductor package according to embodiments. FIG. 16 is an enlarged view of the region R of FIG. 1, and is a view subsequent to FIG. 14.

Referring to FIG. 16, in embodiments, the width W4 of the first portion 151 in the second direction DR2 may substantially be the same as the width W3 of the lower surface of the first connection bump 160 in the second direction DR2.

Although the embodiments of the present disclosure have been described with reference to the accompanying drawings, it will be apparent to those skilled in the art that the present disclosure can be manufactured in various forms without being limited to the above-described embodiments and can be embodied in other specific forms without departing from the spirit and essential characteristics of the present disclosure. Thus, the above embodiments are to be considered in all respects as illustrative and not restrictive.

While example embodiments have been described with reference to the figures, it will be understood by those of ordinary skill in the art that various changes in form and details may be made therein without departing from the spirit and scope as defined by the following claims and their equivalents.

1. A semiconductor package comprising:
a first chip substrate comprising a first surface and a second surface which are opposite to each other;
a through via passing through the first chip substrate;
an upper passivation layer comprising a trench on the second surface of the first chip substrate, the trench exposing at least a portion of the second surface of the first chip substrate;
an upper pad electrically connected with the through via on the trench;
a second chip substrate comprising a third surface opposite to the second surface and a fourth surface opposite to the third surface;
a lower pad electrically connected with the second chip substrate on the third surface of the second chip substrate; and
a connection bump electrically connecting the upper pad with the lower pad, the connection bump contacting the lower pad,
wherein a width of the connection bump on the first surface of the first chip substrate increases as the connection bump becomes farther away from the first surface of the first chip substrate in a vertical direction.

2. The semiconductor package of claim 1, wherein the upper pad comprises a first portion extending along a bottom surface of the trench, a second portion extending along a sidewall of the trench, and a third portion extending along at least a portion of an upper surface of the upper passivation layer.

3. The semiconductor package of claim 2, wherein the connection bump contacts at least a portion of the first portion and at least a portion of the second portion.

4. The semiconductor package of claim 2, wherein a width of a lower surface of the connection bump on the first surface of the first chip substrate is smaller than a width of the first portion.

5. The semiconductor package of claim 1, wherein a width of the trench on the first surface of the first chip substrate decreases as the trench becomes farther away from the second chip substrate in the vertical direction.

6. The semiconductor package of claim 1, wherein a material of the connection bump is different from a material of the upper pad.

7. The semiconductor package of claim 1, wherein a melting point of the connection bump is lower than a melting point of the upper pad.

8. The semiconductor package of claim 1, wherein the connection bump comprises the same material as a material of the upper pad, and does not comprise tin (Sn).

9. The semiconductor package of claim 1, further comprising a seed layer between the connection bump and the lower pad.

10. The semiconductor package of claim 9, wherein a width of the connection bump on the first surface of the first chip substrate is reduced and then increased as the connection bump becomes farther away from the first surface of the first chip substrate in the vertical direction.

11. The semiconductor package of claim 9, wherein the seed layer comprises a first seed layer on the upper pad, and a second seed layer between the first seed layer and the connection bump, the second seed layer comprising a material different from a material of the first seed layer.

12. A semiconductor package comprising:
a first semiconductor chip comprising an upper passivation layer having a trench, and an upper pad extending along a bottom surface of the trench and a sidewall of the trench and at least a portion of an upper surface of the upper passivation layer;
a second semiconductor chip comprising a lower pad on the first semiconductor chip;
a seed layer on the lower pad; and
a connection bump between the upper pad and the seed layer, the connection bump electrically connecting the first semiconductor chip with the second semiconductor chip,
wherein a width of the connection bump on the first semiconductor chip increases toward a first direction oriented toward the second semiconductor chip from the first semiconductor chip, and
wherein a sidewall of the seed layer comprises a portion recessed into the seed layer.

13. The semiconductor package of claim 12, wherein the connection bump contacts the upper pad.

14. The semiconductor package of claim 12, wherein the upper pad comprises copper, and
wherein a melting point of the lower pad is lower than a melting point of the upper pad and the lower pad does not comprise tin (Sn).

15. The semiconductor package of claim 12, wherein the connection bump comprises the same material as a material of the upper pad and does not include tin (Sn).

16-23. (canceled)

24. A semiconductor package comprising:
a package substrate;
a plurality of first semiconductor chips sequentially on the package substrate in a first direction;
an external connection terminal between the package substrate and the plurality of first semiconductor chips, the external connection terminal electrically connecting the package substrate with the plurality of first semiconductor chips; and
a connection bump between the plurality of first semiconductor chips, the connection bump electrically connecting the plurality of first semiconductor chips with each other and comprising aluminum,
wherein each of the plurality of first semiconductor chips comprises:
a chip substrate comprising a first surface opposite to an upper surface of the package substrate and a second surface opposite to the first surface,
a semiconductor device layer on the first surface of the chip substrate,
a lower pad on the semiconductor device layer,
a seed layer on the lower pad,
an upper passivation layer comprising a trench on the second surface of the chip substrate, the trench exposing at least a portion of the second surface of the chip substrate, and
an upper pad extending along a bottom surface of the trench and a sidewall of the trench and at least a portion of an upper surface of the upper passivation layer, including copper,
wherein a width of the connection bump and a width of the trench on the upper surface of the package substrate increase as the connection bump and the trench become farther away from the upper surface of the package substrate in the first direction.

25. The semiconductor package of claim 24, further comprising an air gap between the connection bump and the upper pad.

26. The semiconductor package of claim 24, wherein the connection bump comprises a first connection bump and a second connection bump which are spaced apart from each other in a second direction crossing the first direction, and
wherein a distance between a center of the first connection bump and a center of the second connection bump is less than 20 μm.

27. The semiconductor package of claim 24, further comprising a second semiconductor chip between the package substrate and the plurality of first semiconductor chips, the second semiconductor chip being electrically connected with the package substrate and the plurality of first semiconductor chips.

28. The semiconductor package of claim 24, further comprising:
an interposer between the package substrate and the plurality of first semiconductor chips; and
a second semiconductor chip spaced apart from the plurality of first semiconductor chips on the interposer in a second direction crossing the first direction,
wherein the plurality of first semiconductor chips are electrically connected with the second semiconductor chip through the interposer.
